(19) United States
(12) Patent Application Publication
(10) Pub. No.: US 2026/0333574 A1
(43) Pub. Date: Oct. 22, 2026

(54) CIRCUIT BOARD AND SEMICONDUCTOR PACKAGE COMPRISING SAME

(71) Applicant: LG INNOTEK CO., LTD., Seoul (KR)

(72) Inventors: Yong Ho SON, Seoul (KR); Yong Suk KIM, Seoul (KR); Moo Seong KIM, Seoul (KR)

(73) Assignee: LG INNOTEK CO., LTD., Seoul (KR)

(21) Appl. No.: 19/099,425

(22) PCT Filed: Jul. 31, 2023
(86) PCT No.: PCT/KR2023/011134

§ 371 Date: Jan. 28, 2025

(30) Foreign Application Priority Data
Jul. 29, 2022 (KR) 10-2022-0094462

(51) Int. Cl. H05K 1/02; H10W 42/00; H10W 70/63; H10W 70/654; H10W 70/685; H10W 90/00; H10W 90/10

(52) U.S. Cl. CPC H05K 1/0271; H10W 42/121; H10W 70/635; H10W 70/654; H10W 70/685; H05K 2201/2009; H10W 90/10; H10W 90/401; H10W 90/722; H10W 90/724

(57) ABSTRACT

A circuit board according to an embodiment includes a substrate; and a reinforcement pattern disposed on the substrate, wherein the reinforcement pattern includes: a first reinforcement part extending on the substrate in a first horizontal direction, and a second reinforcement part extending on the substrate in a second horizontal direction perpendicular to the first horizontal direction, and a width of the first reinforcement part is different from a width of the second reinforcement part.

### TECHNICAL FIELD

The present invention relates to a circuit board, and more particularly, to a circuit board having improved warpage characteristics and a semiconductor package including the same.

### BACKGROUND ART

As performances of electric/electronic products progresses, technologies for disposing a greater number of semiconductor devices on a semiconductor package substrate of a limited size are being proposed and studied. However, since a general semiconductor package is based on mounting a single semiconductor device, there is a limit to obtaining a desired performance.

Accordingly, a semiconductor package that mounts a plurality of semiconductor devices using a plurality of circuit boards has been recently provided. This semiconductor package has a structure in which a plurality of semiconductor devices are connected to each other in a horizontal direction and/or a vertical direction on the circuit board. Accordingly, the semiconductor package has the advantage of efficiently using a mounting area of the semiconductor devices and transmitting high-speed signals through a short signal transmission path between the semiconductor devices.

Due to these advantages, the semiconductor package as described above is widely applied to mobile devices, etc.

In addition, semiconductor packages applied to products that provide the Internet of Things (IoT), autonomous vehicles, and high-performance servers are expanding a concept to semiconductor chiplets as a number of semiconductor devices and/or a size of each semiconductor device increases in accordance with a trend of high integration, or as functional parts of the semiconductor devices are divided.

Accordingly, an intercommunication between semiconductor devices and/or semiconductor chiplets is becoming important, and accordingly, there is a trend to dispose an interposer between the circuit board of the semiconductor package and the semiconductor devices.

An interposer can function as a redistribution layer that gradually increases a width or depth of a circuit pattern from the semiconductor device to the semiconductor package in order to facilitate the intercommunication between the semiconductor devices and/or semiconductor chiplets, or to interconnect the semiconductor devices and the semiconductor package substrate, thereby smoothly transmitting electrical signals between the semiconductor device and the semiconductor package substrate having a relatively large circuit pattern compared to the circuit pattern of the semiconductor device.

An interposer may have an area greater than a total area of a plurality of semiconductor devices and/or semiconductor chiplets in order to mount a plurality of semiconductor devices and/or semiconductor chiplets as a whole, or may be disposed only in a portion for interconnection between the semiconductor devices and/or semiconductor chiplets. That is, an area of the interposer may increase as the number of semiconductor devices and/or semiconductor chiplets increases, or an area of the interposer may not increase. However, as the number of semiconductor devices and/or semiconductor chiplets increases, an area of a circuit board of the semiconductor package tends to increase.

Accordingly, as the area of the semiconductor package increases, there is a problem that the semiconductor package warps more. In addition, as the number of semiconductor devices and/or semiconductor chiplets increases, heat generation becomes more severe, and thus there is a problem that heat dissipation characteristics must be further improved.

(Patent Document 1) KR 10-2016-0116838 A

### DISCLOSURE

### Technical Problem

The embodiment provides a circuit board having a novel structure and a semiconductor package including the same.

In addition, the embodiment provides a circuit board having improved warpage characteristics and a semiconductor package including the same.

In addition, the embodiment provides a circuit board having improved heat dissipation characteristics and a semiconductor package including the same.

In addition, the embodiment provides a semiconductor package having improved adhesion between a circuit board and a connection member.

Technical problems to be solved by the proposed embodiments are not limited to the above-mentioned technical problems, and other technical problems not mentioned may be clearly understood by those skilled in the art to which the embodiments proposed from the following descriptions belong.

### Technical Solution

A circuit board according to an embodiment comprises a substrate; and a reinforcement pattern disposed on the substrate, wherein the reinforcement pattern includes: a first reinforcement part extending on the substrate in a first horizontal direction, and a second reinforcement part extending on the substrate in a second horizontal direction perpendicular to the first horizontal direction, and wherein a width of the first reinforcement part is different from a width of the second reinforcement part.

In addition, the width of the first reinforcement part is a width of the first reinforcement part in the second horizontal direction, and the width of the second reinforcement part is a width of the second reinforcement part in the first horizontal direction.

In addition, a width of the substrate in the first horizontal direction is different from a width of the substrate in the second horizontal direction.

In addition, the width of the substrate in the first horizontal direction is greater than the width of the substrate in the second horizontal direction.

In addition, the width of the first reinforcement part in the second horizontal direction satisfies a range of 1.3 to 5 times the width of the second reinforcement part in the first horizontal direction.

In addition, the width of the first reinforcement part in the second horizontal direction satisfies a range of 50 μm to 90 μm.

In addition, the reinforcement pattern is disposed on the substrate in a closed loop shape, and the first reinforcement part is connected to the second reinforcement part.

Meanwhile, the semiconductor package according to the embodiment comprises the circuit board; and a connection member disposed on the circuit board, and wherein the circuit board includes an electrode layer connected to the connection member.

In addition, the electrode layer includes: a reinforcement electrode corresponding to the reinforcement pattern; and a signal electrode separated from the reinforcement electrode and electrically connected to the connection member.

In addition, the reinforcement electrode is a power line for supplying power to the connection member.

In addition, the reinforcement electrode includes a plurality of reinforcement electrodes disposed in different layers, and the circuit board includes a through part connecting the plurality of reinforcement electrodes.

In addition, the through part includes a first through part vertically overlapping the first reinforcement part; and a second through part vertically overlapping the second reinforcement part.

In addition, a width of the first through part in the first horizontal direction is greater than a width of the first through part in the second horizontal direction.

In addition, the width of the second through part in the first horizontal direction is smaller than the width of the second through part in the second horizontal direction.

In addition, the circuit board includes a first reinforcement electrode, the connection member includes a second reinforcement electrode, and the first reinforcement electrode and the second reinforcement electrode do not overlap in a vertical direction.

In addition, the circuit board includes a first reinforcement electrode and a first signal electrode, the connection member includes a second reinforcement electrode and a second signal electrode, and the first reinforcement electrode and the second reinforcement electrode overlap in the vertical direction.

In addition, the semiconductor package includes a first connecting part disposed between the first reinforcement electrode and the second reinforcement electrode; and a second connecting part disposed between the first signal electrode and the second signal electrode.

### Advantageous Effects

The circuit board of the embodiment includes a substrate and a reinforcement pattern disposed on the substrate. The reinforcement pattern includes a first part disposed on the substrate in a first horizontal direction and a second part disposed in a second horizontal direction different from the first horizontal direction. At this time, the first part is disposed on the substrate to extend long in the first horizontal direction. In addition, the second part is disposed on the substrate to extend long in the second horizontal direction. At this time, a width of the first part in the second horizontal direction is different from a width of the second part in the first horizontal direction. That is, the embodiment allows the width of the first part disposed in a direction in which relatively large bending occurs in the circuit board to be greater than the width of the second part. For example, a width of the substrate in the first horizontal direction is greater than a width of the substrate in the second horizontal direction. In addition, a width of the first part of the reinforcement pattern is greater than the width of the second part. Therefore, the embodiment can more efficiently prevent bending of the circuit board by controlling the width of the reinforcement pattern. Accordingly, the embodiment can improve the bending characteristics of the circuit board. Furthermore, the embodiment can improve warpage bending characteristics while minimizing an area of the reinforcement pattern on the substrate by controlling the width. Accordingly, the embodiment can minimize the increase in the area of the circuit board by the reinforcement pattern.

Furthermore, the embodiment can improve bonding characteristics between the circuit board and the connection member. Here, the connection member can be a separate external substrate bonded to the circuit board, or can be a semiconductor device.

Specifically, a connecting part is disposed between the circuit board and the connection member. At this time, when the circuit board is bent, there may be a problem that the connecting part is separated from the circuit board and/or the connection member. Furthermore, when the circuit board is bent, a positional alignment between the circuit board and the connection member may be deteriorated.

Unlike this, the embodiment can improve a bonding force between the circuit board and the connection member by improving the warpage characteristics of the circuit board. Furthermore, the embodiment can improve an alignment of a bonding position between the circuit board and the connection member. Accordingly, the embodiment can improve physical characteristics and/or electrical characteristics of the semiconductor package.

Meanwhile, the reinforcement patterns of the embodiment are respectively disposed on different layers of the circuit board. Furthermore, the circuit board includes a reinforcement through part connecting between the reinforcement patterns disposed on different layers. The embodiment can further improve the warpage characteristics of the circuit board and the warpage characteristics of the semiconductor package by additionally arranging the reinforcement through part.

Meanwhile, the reinforcement pattern is a reinforcement electrode which is a part of an electrode layer disposed on the circuit board. In addition, the reinforcement electrode may include a metal material. Through this, the embodiment can improve the warpage characteristics of the circuit board while dissipating heat generated in the circuit board to an outside by using the reinforcement pattern. Through this, the embodiment can further improve heat dissipation characteristics of the circuit board.

Furthermore, the semiconductor package of the embodiment includes a circuit board including a first reinforcement pattern and a connection member including a second reinforcement pattern.

At this time, the embodiment allows the first reinforcement pattern and the second reinforcement pattern to overlap in a vertical direction. Specifically, the semiconductor package includes a connecting part disposed between the circuit board and the connection member. In addition, the connecting part includes a first connecting part disposed between the first reinforcement pattern of the circuit board and the second reinforcement pattern of the connection member. At this time, the embodiment connects the first reinforcement pattern of the circuit board and the second reinforcement pattern of the second circuit board using the first connecting part. Accordingly, the embodiment can further improve the bonding strength between the circuit board and the connection member. In addition, the embodiment can transfer heat generated from the circuit board to the connection member or transfer heat generated from the connection member to the circuit board through the first connecting part. Accordingly, the embodiment can further improve the heat dissipation characteristics of the semiconductor package.

Furthermore, the first reinforcement pattern can be used as a power terminal for supplying power from the circuit board to the connection member. Accordingly, the embodiment can stably supply power to the connection member, and thereby enable the connection member to operate stably.

Specifically, the circuit board can supply sufficient power necessary for driving the connection member by providing a power signal to the connection member using the reinforcement pattern. Accordingly, the embodiment can improve driving characteristics of the connection member. That is, the embodiment can solve a problem of insufficient power provided to the connection member. That is, recently, a function provided by the connection member has increased or a performance of the connection member has been improved, so the driving power required by the connection member can increase. Accordingly, the embodiment can supply a power signal to the connection member through the reinforcement pattern, and through this, the embodiment can further improve electrical reliability of the semiconductor package.

### DESCRIPTION OF DRAWINGS

FIG. 1 is a drawing showing a semiconductor package according to a comparative example.

FIG. 2a is a cross-sectional view showing a semiconductor package according to a first embodiment.

FIG. 2b is a cross-sectional view showing a semiconductor package according to a second embodiment.

FIG. 2c is a cross-sectional view showing a semiconductor package according to a third embodiment.

FIG. 2d is a cross-sectional view showing a semiconductor package according to a fourth embodiment.

FIG. 2e is a cross-sectional view showing a semiconductor package according to a fifth embodiment.

FIG. 2f is a cross-sectional view showing a semiconductor package according to a sixth embodiment.

FIG. 2g is a cross-sectional view showing a semiconductor package according to a seventh embodiment.

FIG. 3 is a cross-sectional view showing a circuit board according to a first embodiment.

FIG. 4 is a perspective view schematically showing a circuit board according to an embodiment.

FIG. 5 is a plan view showing a reinforcement pattern according to an embodiment.

FIG. 6 is a drawing showing a circuit board according to a second embodiment.

FIG. 7 is a drawing showing a circuit board according to a third embodiment.

FIG. 8 is a plan view showing reinforcement electrodes and reinforcement through parts of a circuit board of FIG. 7.

FIG. 9a is a drawing showing a semiconductor package including a plurality of circuit boards according to one embodiment.

FIG. 9b is a drawing showing a semiconductor package including a plurality of circuit boards according to another embodiment.

FIG. 10 is a cross-sectional view showing a semiconductor package according to one embodiment.

### BEST MODEL

Hereinafter, embodiments of the present disclosure will be described in detail with reference to the accompanying drawings.

However, the spirit and scope of the present disclosure is not limited to a part of the embodiments described, and may be implemented in various other forms, and within the spirit and scope of the present disclosure, one or more of the elements of the embodiments may be selectively combined and replaced.

In addition, unless expressly otherwise defined and described, the terms used in the embodiments of the present disclosure (including technical and scientific terms) may be construed the same meaning as commonly understood by one of ordinary skill in the art to which the present disclosure belongs, and the terms such as those defined in commonly used dictionaries may be interpreted as having a meaning that is consistent with their meaning in the context of the relevant art. In addition, the terms used in the embodiments of the present disclosure are for describing the embodiments and are not intended to limit the present disclosure.

In this specification, the singular forms may also include the plural forms unless specifically stated in the phrase, and may include at least one of all combinations that may be combined in A, B, and C when described in “at least one (or more) of A (and), B, and C”. Further, in describing the elements of the embodiments of the present disclosure, the terms such as first, second, A, B, (a), and (b) may be used.

These terms are only used to distinguish the elements from other elements, and the terms are not limited to the essence, order, or order of the elements. In addition, when an element is described as being “connected”, “coupled”, or “contacted” to another element, it may include not only when the element is directly “connected” to, “coupled” to, or “contacted” to other elements, but also when the element is “connected”, “coupled”, or “contacted” by another element between the element and other elements.

In addition, when described as being formed or disposed “on (over)” or “under (below)” of each element, the “on (over)” or “under (below)” may include not only when two elements are directly connected to each other, but also when one or more other elements are formed or disposed between two elements. Further, when expressed as “on (over)” or “under (below)”, it may include not only the upper direction but also the lower direction based on one element.

### Comparative Example (Structure and Problems of Prior Art)

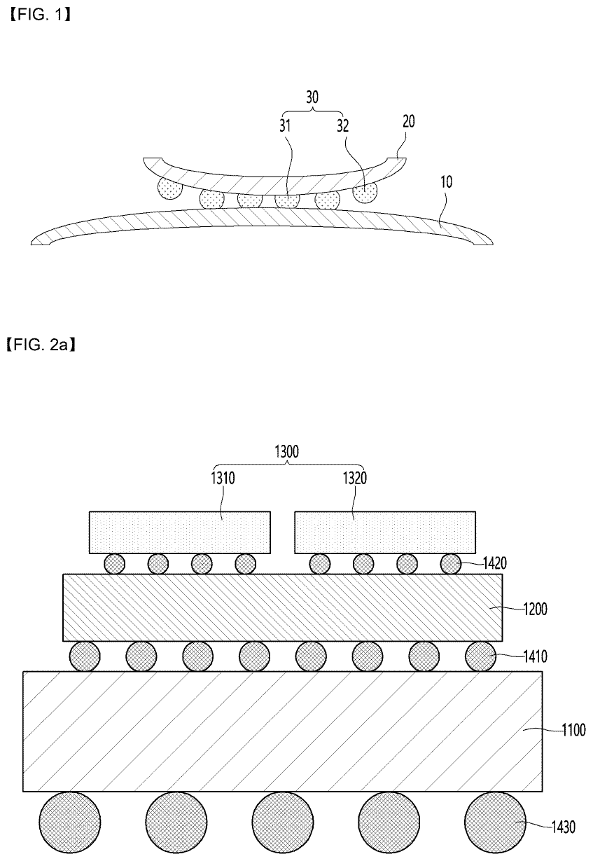

FIG. 1 is a drawing showing a semiconductor package according to a comparative example.

Referring to FIG. 1, the semiconductor package includes a plurality of components 10 and 20 that are electrically connected to each other with a connecting part 30 interposed therebetween.

In one embodiment, the plurality of components 10 and 20 may be a first circuit board and a second circuit board. In another embodiment, the plurality of components 10 and 20 may be a circuit board and a semiconductor device.

At this time, as a demand for high-performance semiconductor devices applied to the semiconductor package increases, planar areas of the plurality of components 10 and 20 is increasing. In addition, as the planar area increases, there is a problem that the plurality of components 10 and 20 are bent more.

For example, the semiconductor package includes a first component 10 and a second component 20.

At this time, the first component 10 includes a plurality of first insulating layers and a first electrode layer. At this time, there is a problem that the first component 10 is bent in a specific direction depending on a type of insulating material forming the first insulating layer and a wiring density occupied by the electrode layer on the first insulating layer.

The semiconductor package electrically connects the second component 20 with the connecting part 30 disposed on the first component 10.

At this time, a problem occurs that the first configuration 10 is bent in a specific direction. Furthermore, there is a problem that the second configuration 20 is bent in a specific direction.

Accordingly, when the first component 10 and the second component 20 are each bent in a specific direction, there is a problem that at least a part of the connecting part 30 is separated from the first component 10 or the second component 20.

For example, as shown in FIG. 1, when at least one of the first component 10 and the second component 20 is bent in a specific direction, the connecting part 30 includes a first connecting part 31 normally connected between the first component 10 and the second component 20 and a second connecting part 32 separated from at least one of the first component 10 and the second component 20.

In addition, when the connecting part 30 includes the second connecting part 32, an electrical reliability problem may occur due to the first configuration 10 and the second configuration 20 not being electrically connected to each other.

Furthermore, in the semiconductor package of the comparative example, as a planar area of the first component 10 or the second component 20 increases, the heating of the first component 10 or the second component 20 becomes more severe.

That is, as the planar area of the semiconductor package increases, it has a problem of greater bending and a problem of greater improvement in heat dissipation characteristics.

Therefore, the embodiment improves warpage characteristics and heat dissipation characteristics of the semiconductor package so as to further improve product reliability of the semiconductor package.

### Electronic Device

Before describing the embodiment, an electronic device to which the semiconductor package of the embodiment is applied will be briefly described. The electronic device includes a main board (not shown). The main board may be physically and/or electrically connected to various components. For example, the main board may be connected to the semiconductor package of the embodiment. Various semiconductor devices may be mounted on the semiconductor package.

The semiconductor device may include an active device and/or a passive device. The active device may be a semiconductor device in the form of an integrated circuit (IC) in which hundreds to millions of devices are integrated in one semiconductor device. The semiconductor device may be a logic chip, a memory chip, or the like. The logic chip may be a central processor (CPU), a graphics processor (GPU), or the like. For example, the logic chip may be an application processor (AP) chip including at least one of a central processor (CPU), a graphics processor (GPU), a digital signal processor, a cryptographic processor, a microprocessor and a microcontroller, or an analog-digital converter, an application-specific IC (ASIC), or the like, or a chip set comprising a specific combination of those listed so far.

The memory chip may be a stack memory such as HBM. The memory chip may also include a memory chip such as volatile memory (e.g., DRAM), non-volatile memory (e.g., ROM), flash memory, and the like.

On the other hand, a product group to which the semiconductor package of the embodiment is applied may be any one of CSP (Chip Scale Package), FC-CSP (Flip Chip-Chip Scale Package), FC-BGA (Flip Chip Ball Grid Array), POP (Package on Package) and SIP (System in Package), but is not limited thereto.

In addition, the electronic device may be a smart phone, a personal digital assistant, a digital video camera, a digital still camera, a vehicle, a high-performance server, a network system, computer, monitor, tablet, laptop, netbook, television, video game, smart watch, automotive, or the like. However, the embodiment is not limited thereto, and may be any other electronic device that processes data in addition to these.

Hereinafter, a semiconductor package including a circuit board according to an embodiment will be described. The semiconductor package of the embodiment may have various package structures including a circuit board to be described later. In addition, the circuit board in one embodiment may be a package substrate described below, and the circuit board in another embodiment may be an interposer described below.

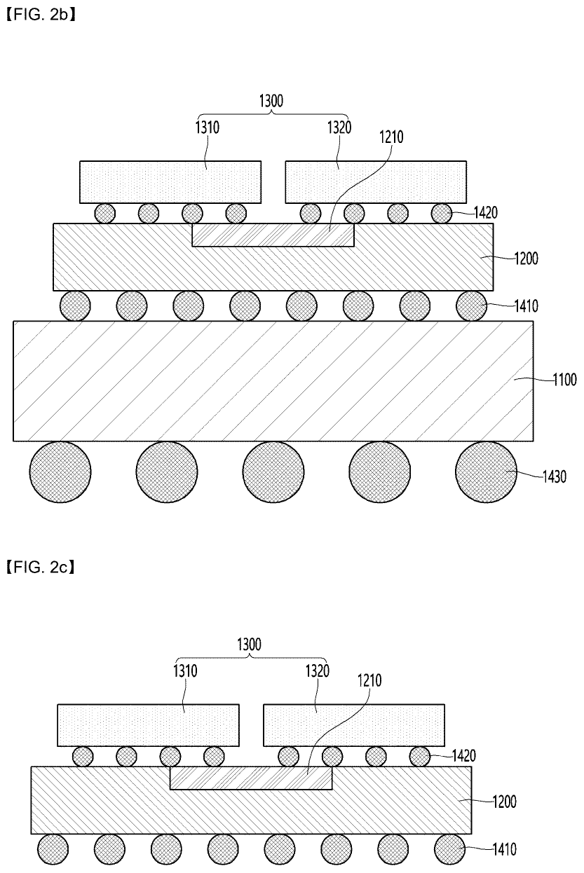

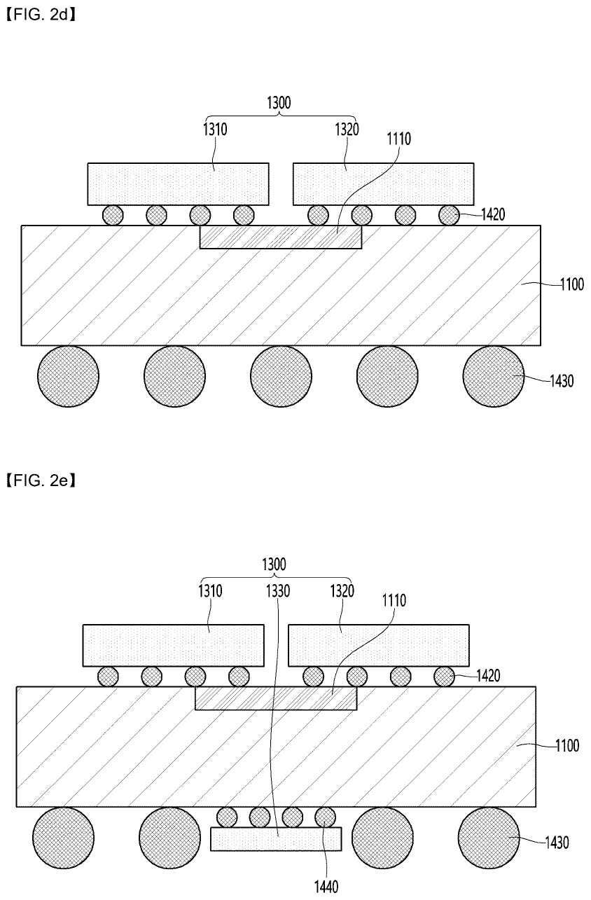

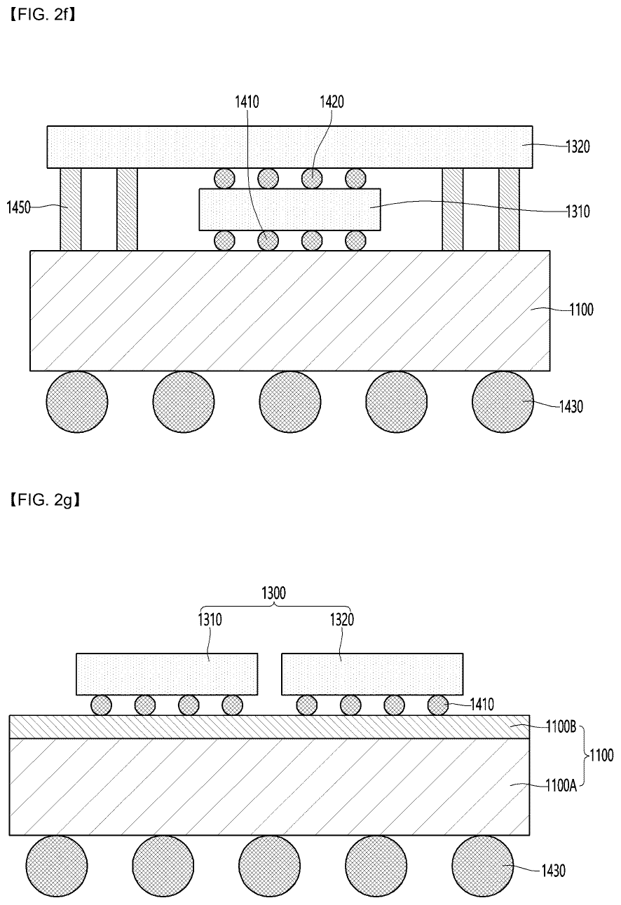

FIG. 2b is a cross-sectional view showing a semiconductor package according to a second embodiment, FIG. 2c is a cross-sectional view showing a semiconductor package according to a third embodiment, FIG. 2d is a cross-sectional view showing a semiconductor package according to a fourth embodiment, FIG. 2e is a cross-sectional view showing a semiconductor package according to a fifth embodiment, FIG. 2f is a cross-sectional view showing a semiconductor package according to a sixth embodiment, and FIG. 2g is a cross-sectional view showing a semiconductor package according to a seventh embodiment.

Referring to FIG. 2a, the semiconductor package according to the first embodiment may include a first circuit board 1100, a second circuit board 1200, and a semiconductor device 1300. At this time, one of the first circuit board 1100 and the second circuit board 1200 may be a main circuit board, and another one may be referred to as a connection member together with a semiconductor device 1300.

The first circuit board 1100 means a package substrate.

For example, the first circuit board 1100 may provide a space to which at least one external circuit board is coupled. The external circuit board may refer to a second circuit board 1200 coupled to the first circuit board 1100. Also, the external circuit board may refer to a main board included in an electronic device coupled to a lower portion of the first circuit board 1100.

Also, although not shown in the drawing, the first circuit board 1100 may provide a space in which at least one semiconductor device is mounted.

The first circuit board 1100 includes at least one insulating layer, an electrode disposed on the at least one insulating layer, and a through portion passing through the at least one insulating layer.

A second circuit board 1200 is disposed on the first circuit board 1100.

The second circuit board 1200 may be an interposer. For example, the second circuit board 1200 may provide a space in which at least one semiconductor device is mounted. The second circuit board 1200 may be connected to the at least one semiconductor device 1300. For example, the second circuit board 1200 may provide a space in which the first semiconductor device 1310 and the second semiconductor device 1320 are mounted. The second circuit board 1200 may electrically connect the first and second semiconductor devices 1310 and 1320 and the first circuit board 1100 while electrically connecting the first semiconductor device 1310 and the second semiconductor device 1320. That is, the second circuit board 1200 may perform a horizontal connection function between a plurality of semiconductor devices and a vertical connection function between the semiconductor devices and the package substrate.

FIG. 2a illustrates that the first and second semiconductor devices 1310 and 1320 are disposed on the second circuit board 1200, but is not limited thereto. For example, one semiconductor device may be disposed on the second circuit board 1200, or alternatively, three or more semiconductor devices may be disposed.

The second circuit board 1200 may be disposed between at least one semiconductor device 1300 and the first circuit board 1100.

In an embodiment, the second circuit board 1200 may be an active interposer that functions as a semiconductor device. When the second circuit board 1200 functions as a semiconductor device, the semiconductor package of the embodiment may have a structure that is vertically stacked on the first circuit board 1100 and may have functions of multiple logic chips. Having the function of a logic chip may mean that it may have functions of an active device and a passive device. In a case of an active device, characteristics of current and voltage may not be linear unlike a passive device, and in a case of an active interposer, it may have the function of an active device. In addition, the active interposer may perform a function of a corresponding logic chip while performing a signal transmission function between a second logic chip disposed thereon and the first circuit board 1100.

According to another embodiment, the second circuit board 1200 may be a passive interposer. For example, the second circuit board 1200 may function as a signal relay between the semiconductor device 1300 and the first circuit board 1100, and can have a passive device function such as a resistor, capacitor, or inductor. For example, a number of terminals of the semiconductor device 1300 is gradually increasing due to 5G, Internet of Things (IOT), increased image quality, and increased communication speed. That is, the number of terminals provided in the semiconductor device 1300 increases, thereby reducing the width of the terminals or an interval between the plurality of terminals. In this case, the first circuit board 1100 is connected to the main board of the electronic device. There is a problem in that the thickness of the first circuit board 1100 increases or the layer structure of the first circuit board 1100 becomes complicated in order for the electrodes provided on the first circuit board 1100 to have a width and an interval to be respectively connected to the semiconductor device 1300 and the main board. Accordingly, in the first embodiment, the second circuit board 1200 is disposed on the first circuit board 1100 and the semiconductor device 1300. In addition, the second circuit board 1200 may include electrodes having a fine width and an interval corresponding to the terminals of the semiconductor device 1300.

the semiconductor device 1300 may be an application processor (AP) chip including at least one of a central processor (CPU), a graphics processor (GPU), a digital signal processor, a cryptographic processor, a microprocessor and a microcontroller, or an analog-digital converter, an application-specific IC (ASIC), or the like, or a chip set comprising a specific combination of those listed so far. The memory chip may be a stack memory such as HBM. The memory chip may also include a memory chip such as volatile memory (e.g., DRAM), non-volatile memory (e.g., ROM), flash memory, and the like.

Meanwhile, the semiconductor package of the first embodiment may include a connecting part.

For example, the semiconductor package includes a first connecting part 1410 disposed between the first circuit board 1100 and the second circuit board 1200. The first connecting part 1410 electrically connects the second circuit board 1200 to the first circuit board 1100 while coupling them.

For example, the semiconductor package may include the second connecting part 1420 disposed between the second circuit board 1200 and the semiconductor device 1300. The second connecting part 1420 may electrically connect the semiconductor device 1300 to the second circuit board 1200 while coupling them.

The semiconductor package includes a third connecting part 1430 disposed on a lower surface of the first circuit board 1100. The third connecting part 1430 may electrically connect the first circuit board 1100 to the main board while coupling them.

At this time, the first connecting part 1410, the second connecting part 1420, and the third connecting part 1430 may electrically connect between the plurality of components by using at least one bonding method of wire bonding, solder bonding and metal-to-metal direct bonding. That is, since the first connecting part 1410, the second connecting part 1420, and the third connecting part 1430 have a function of electrically connecting a plurality of components, when the metal-to-metal direct bonding is used, the connecting part of the semiconductor package may be understood as an electrically connected portion, not a solder or wire.

The wire bonding method may refer to electrically connecting a plurality of components using a conductive wire such as gold (Au). Also, the solder bonding method may electrically connect a plurality of components using a material containing at least one of Sn, Ag, and Cu. In addition, the metal-to-metal direct bonding method may refer to recrystallization by applying heat and pressure between a plurality of components without the presence of solder, wire, conductive adhesive, etc. and to directly bond between the plurality of components. In addition, the metal-to-metal direct bonding method may refer to a bonding method by the second connecting part 1420. In this case, the second connecting part 1420 may mean a metal layer formed between a plurality of components by the recrystallization.

Specifically, the first connecting part 1410, the second connecting part 1420, and the third connecting part 1430 may couple a plurality of components to each other by a thermal compression (TC) bonding method. The TC bonding may refer to a method of directly coupling a plurality of components by applying heat and pressure to the first connecting part 1410, the second connecting part 1420, and the third connecting part 1430.

In this case, at least one of the first circuit board 1100 and the second circuit board 1200 may include a protrusion provided in the electrode on the first connecting part 1410, the second connecting part 1420, and the third connecting part 1430 are disposed. The protrusion may protrude outward from the first circuit board 1100 or the second circuit board 1200.

The protrusion may be referred to as a bump. The protrusion may also be referred to as a post. The protrusion may also be referred to as a pillar. Preferably, the protrusion may refer to an electrode on which a second connecting part 1420 for coupling with the semiconductor device 1300 is disposed among the electrodes of the second circuit board 1200. That is, as the pitch of the terminals of the semiconductor device 1300 becomes finer, a short circuit may occur between the plurality of second connecting parts 1420 that are respectively connected to the plurality of terminals of the semiconductor device 1300 by a conductive adhesive such as a solder. Therefore, in the embodiment, thermal compression bonding may be performed to reduce a volume of the second connecting part 1420, and in order to secure diffusion prevention and alignment to prevent an intermetallic compound (IMC) formed between a conductive adhesive such as solder and a protrusion from diffusing into the interposer and/or the circuit board, a protrusion may be included in the electrode of the second circuit board 1200 on which the second connecting part 1420 is placed.

Meanwhile, referring to FIG. 2b, the semiconductor package of the second embodiment is different from the semiconductor package of the first embodiment in that the connection member 1210 is disposed on the second circuit board 1200. The connection member 1210 may be referred to as a bridge substrate. For example, the connection member 1210 may include a redistribution layer. The connection member 1210 may perform a function of electrically connecting a plurality of semiconductor devices horizontally to each other. For example, since the area that a semiconductor device should generally have been too large, the connection member 1210 may include a redistribution layer. Since the semiconductor package and the semiconductor device have a large difference in a width or spacing of the circuit pattern, etc., a buffering role of the circuit pattern for electrical connection is required. The buffering role may mean having a size between a width or spacing of the circuit pattern of the semiconductor package and a width or spacing of the circuit pattern of the semiconductor device, and the redistribution layer may include a function of performing the buffering role.

In an embodiment, the connection member 1210 may be a silicon bridge. That is, the connection member 1210 may include a silicon substrate and a redistribution layer disposed on the silicon substrate.

In another embodiment, the connection member 1210 may be an organic bridge. For example, the connection member 1210 may include an organic material. For example, the connection member 1210 includes an organic substrate including an organic material instead of the silicon substrate.

The connection member 1210 may be embedded in the second circuit board 1200, but is not limited thereto. For example, the connection member 1210 may be disposed on the second circuit board 1200 to have a protruding structure.

Also, the second circuit board 1200 may include a cavity, and the connection member 1210 may be disposed in the cavity of the second circuit board 1200.

The connection member 1210 may horizontally connect a plurality of semiconductor devices disposed on the second circuit board 1200. Furthermore, the connection member in another sense may mean a plurality of semiconductor devices, and may also refer to one of the first circuit board and the second circuit board.

Referring to FIG. 2c, the semiconductor package according to the third embodiment includes a second circuit board 1200 and a semiconductor device 1300. In this case, the semiconductor package of the third embodiment has a structure in which the first circuit board 1100 is removed compared to the semiconductor package of the second embodiment.

That is, the second circuit board 1200 of the third embodiment may function as a package substrate while performing an interposer function.

The first connecting part 1410 disposed on the lower surface of the second circuit board 1200 may couple the second circuit board 1200 to the main board of the electronic device.

Referring to FIG. 2d, the semiconductor package according to the fourth embodiment includes a first circuit board 1100 and a semiconductor device 1300.

In this case, the semiconductor package of the fourth embodiment has a structure in which the second circuit board 1200 is removed compared to the semiconductor package of the second embodiment.

That is, the first circuit board 1100 of the fourth embodiment can function as a package substrate while also performing the function of connecting the semiconductor device 1300 and a main board. To this end, the first circuit board 1100 may include a connection member 1110 for connecting the plurality of semiconductor devices. The connection member 1110 may be a silicon bridge or an organic material bridge connecting a plurality of semiconductor devices.

Referring to FIG. 2e, the semiconductor package of the fifth embodiment further includes a third semiconductor device 1330 compared to the semiconductor package of the fourth embodiment.

To this end, a fourth connecting part 1440 is disposed on the lower surface of the first circuit board 1100.

In addition, a third semiconductor device 1330 may be disposed on the fourth connecting part 1400. That is, the semiconductor package of the fifth embodiment may have a structure in which semiconductor devices are mounted on upper and lower sides, respectively.

In this case, the third semiconductor device 1330 may have a structure disposed on the lower surface of the second circuit board 1200 in the semiconductor package of FIG. 2c.

Referring to FIG. 2f, the semiconductor package according to the sixth embodiment includes a first circuit board 1100.

A first semiconductor device 1310 may be disposed on the first circuit board 1100. To this end, a first connecting part 1410 is disposed between the first circuit board 1100 and the first semiconductor device 1310.

In addition, the first circuit board 1100 includes a conductive coupling portion 1450. The conductive coupling portion 1450 may further protrude from the first circuit board 1100 toward the second semiconductor device 1320. The conductive coupling portion 1450 may be referred to as a bump or, alternatively, may also be referred to as a post. The conductive coupling portion 1450 may be disposed to have a protruding structure on an electrode disposed on an uppermost side of the first circuit board 1100.

A second semiconductor device 1320 may be disposed on the conductive coupling portion 1450. In this case, the second semiconductor device 1320 may be connected to the first circuit board 1100 through the conductive coupling portion 1450. In addition, a second connecting part 1420 may be disposed on the first semiconductor device 1310 and the second semiconductor device 1320.

Accordingly, the second semiconductor device 1320 may be electrically connected to the first semiconductor device 1310 through the second connecting part 1420.

That is, the second semiconductor device 1320 is connected to the first circuit board 1100 through the conductive coupling portion 1450, and is also connected to the first semiconductor device 1310 through the second connecting part 1420.

In this case, the second semiconductor device 1320 may receive a power signal and/or electric power through the conductive coupling portion 1450. Also, the second semiconductor device 1320 may transmit and receive a communication signal to and from the first semiconductor device 1310 through the second connecting part 1420.

The semiconductor package according to the sixth embodiment provides a power signal and/or electric power to the second semiconductor device 1320 through the conductive coupling portion 1450, thereby providing sufficient power for driving the second semiconductor device 1320 or enabling smooth control of a power operation.

Accordingly, the embodiment may improve the driving characteristics of the second semiconductor device 1320. That is, the embodiment may solve a problem of insufficient power provided to the second semiconductor device 1320. Furthermore, in the embodiment, at least one of a power signal, an electric power, and a communication signal of the second semiconductor device 1320 are provided through different paths through the conductive coupling portion 1450 and the second connecting part 1420. Through this, the embodiment can solve the problem that the communication signal is lost due to the power signal. For example, the embodiment may minimize mutual interference between communication signals of power signals.

Meanwhile, the second semiconductor device 1320 in the sixth embodiment may have a POP (Package On Package) structure in which a plurality of package substrates are stacked and may be disposed on the first circuit board 1100. For example, the second semiconductor device 1320 may be a memory package including a memory chip. In addition, the memory package may be coupled on the conductive coupling portion 1450. In this case, the memory package may not be connected to the first semiconductor device 1310.

Referring to FIG. 2g, the semiconductor package according to the seventh embodiment includes a first circuit board 1100, a first connecting part 1410, a first connecting part 1410, a semiconductor device 1300, and a third connecting part 1430.

In this case, the semiconductor package of the seventh embodiment is different from the semiconductor package of the fourth embodiment in that the first circuit board 1100 includes a plurality of substrate layers while the connection member 1110 is removed.

The first circuit board 1100 includes a plurality of circuit board layers. For example, the first circuit board 1100 may include a first circuit board layer 1100A corresponding to a package substrate and a second circuit board layer 1100B corresponding to a redistribution layer of the connection member.

In other words, the semiconductor package of the seventh embodiment includes a first circuit board layer 1100A and a second circuit board layer 1100B in which the first circuit board (package substrate, 1100) and the second circuit board (interposer, 1200) disclosed in FIG. 2a are integrally formed. A material of the insulating layer of the second circuit board layer 1100B may be different from a material of an insulating layer of the first substrate layer 1100A. For example, the material of an insulating layer of the second circuit board layer 1100B may include a photocurable material. For example, the second circuit board layer 1100B may be a photo imageable dielectric (PID). In addition, since the second circuit board layer 1100B includes a photocurable material, it is possible to miniaturize the electrode. Accordingly, in the seventh embodiment, the second circuit board layer 1100B may be formed by sequentially stacking an insulating layer of a photo-curable material on the first circuit board layer 1100A and forming a miniaturized electrode on the insulating layer of the photo-curable material. Accordingly, the second circuit board layer 1100B may include a redistribution layer function including a micro-electrode and may include a function of horizontally connecting a plurality of semiconductor devices 1310 and 1320.

Before describing a circuit board of the embodiment, a circuit board described below may mean any one of a plurality of circuit boards included in the previous semiconductor package.

For example, in an embodiment, a circuit board described below may refer to at least one of the first circuit board 1100, the second circuit board 1200, and the connection member (or bridge substrate, 1110 and 1210) shown in any one of FIGS. 2a to 2g.

FIG. 3 is a cross-sectional view showing a circuit board according to a first embodiment.

Referring to FIG. 3, the circuit board 100 according to the first embodiment includes a first insulating layer 110, a second insulating layer 150, a third insulating layer 160, an electrode layer 120, a through part 130, and an insulating member 140.

The first insulating layer 110 of the circuit board 100 may have a layer structure of at least one layer. Preferably, the first insulating layer 110 of the circuit board 100 may have a plurality of laminated structures. The laminated structures may be distinguished by the through part 130, and may be distinguished by a difference in width between the through part 130 and the electrode layer 120. That is, a width of a lower surface of the electrode layer 120 may be greater than a width of an upper surface of the through part 130, and the laminated structures may be distinguished through this. Through the above-described laminated structure, the circuit board 100 of the embodiment can electrically efficiently connect at least one semiconductor device and/or the second circuit board to the main board.

At this time, the first insulating layer 110 of the circuit board 100 in FIG. 3 is illustrated as having a five-layer structure, but is not limited thereto. For example, the first insulating layer 110 of the circuit board 100 may have four or fewer layers, or may have six or more layers. The first insulating layer 110 may be referred to as a supporting substrate that supports the circuit board 100, and thus may be referred to as a ‘substrate’.

In a case where the first insulating layer 110 of the circuit board 100 has a multiple-layer structure, a plurality of first insulating layers of the circuit board 100 may include a same insulating material, but are not limited thereto. For example, at least one of the plurality of first insulating layers of the circuit board 100 may include an insulating material different from an insulating material of another first insulating layer.

The first insulating layer 110 of the circuit board 100 may be rigid or flexible. For example, the first insulating layer 110 of the circuit board 100 may include glass or plastic. For example, the first insulating layer 110 of the circuit board 100 may include chemically strengthened/semi-strengthened glass such as soda lime glass or aluminosilicate glass. For example, the first insulating layer 110 of the circuit board 100 may include a strengthened or flexible plastic such as polyimide (PI), polyethylene terephthalate (PET), propylene glycol (PPG), or polycarbonate (PC). For example, the first insulating layer 110 of the circuit board 100 may include sapphire. For example, the first insulating layer 110 of the circuit board 100 may include an optically isotropic film. For example, the first insulating layer 110 of the circuit board 100 may include COC (Cyclic Olefin Copolymer), COP (Cyclic Olefin Polymer), optically isotropic polycarbonate (PC), or optically isotropic polymethyl methacrylate (PMMA). For example, the first insulating layer 110 of the circuit board 100 may be formed of a material including an inorganic filler and an insulating resin. For example, the first insulating layer 110 of the circuit board 100 may have a structure in which an inorganic filler of silica or alumina is disposed in a thermosetting resin or a thermoplastic resin.

The first insulating layer 110 may have a structure in which a plurality of different insulating materials are laminated, and an exemplary arrangement structure will be described in more detail as follows.

In one embodiment, the first insulating layer 110 may include a first layer corresponding to a core layer including a reinforcing member. In addition, the first insulating layer 110 may include a plurality of second layers that are respectively disposed on upper and lower portions of the core layer and do not include a reinforcing member. In this case, the circuit board 100 may be a core substrate. The reinforcing member may also be referred to as a reinforcing fiber or a glass fiber.

The reinforcing member may mean a glass fiber material extending along a horizontal direction of the first insulating layer 110, and may have a different meaning from an inorganic filler that is spaced apart from each other. That is, the reinforcing member of the first layer may have a different length or width along the horizontal direction from the filler of the second layer. For example, the glass fiber may be extended to have a width greater than the width of the first layer. Here, the meaning of having a width greater than the width of the first layer may mean that the glass fibers can be disposed in a shape that is bent in the horizontal direction. In addition, even if the second layer includes a filler, an effect of preventing problems such as bending is not as great as that of the glass fibers of the first layer, so the reinforcing member is described separately from the filler of the second layer.

In another embodiment, the first insulating layer 110 of the circuit board 100 may be a coreless substrate that does not include a core. For example, the first insulating layer 110 of the circuit board 100 may include an organic material that does not include a reinforcing member that has excellent processability, enables slimming of the circuit board 100, and enables miniaturization of the electrode layer 120 of the circuit board 100. For example, the first insulating layer 110 of the circuit board 100 may use ABF (Ajinomoto Build-up Film), a product released by Ajinomoto Co., Ltd., as an example, and the first insulating layer 110 of the circuit board 100 may use FR-4, BT (Bismaleimide Triazine), PID (Photo Imageable Dielectric resin), BT, etc. For example, the first insulating layer 110 may include a plurality of layers composed of ABF.

At this time, if the first insulating layer 110 of the circuit board 100 is composed of only ABF that does not include a reinforcing member, the warpage characteristics of the circuit board 100 may be deteriorated. Therefore, if the first insulating layer 110 of the circuit board 100 is composed of ABF (Ajinomoto Build-up Film), at least one ABF among the ABFs constituting the plurality of insulating layers of the circuit board 100 may include a reinforcing member that can improve the warpage characteristics.

For example, the first insulating layer 110 of the circuit board 100 includes a first layer composed of a first ABF including a resin and a filler. In addition, the first insulating layer 110 of the circuit board 100 includes a layer composed of a second ABF further including a reinforcing member in the first ABF. At this time, the reinforcing member included in the second ABF may include a GCP (Glass Core Primer) material, but is not limited thereto.

A layer of the first insulating layer 110 of the circuit board 100 that does not include the reinforcing member can have a thickness in a range of 10 μm to 40 μm. Preferably, the layer of the first insulating layer 110 of the circuit board 100 that does not include the reinforcing member can satisfy a thickness in a range of 15 μm to 35 μm. More preferably, the layer of the first insulating layer 110 of the circuit board 100 that does not include the reinforcing member can satisfy a thickness in a range of 18 μm to 32 μm. If the thickness of the layer of the first insulating layer 110 of the circuit board 100 that does not include the reinforcing member is less than 10 μm, the warpage characteristics of the circuit board 100 may deteriorate. In addition, if the thickness of the layer of the first insulating layer 110 of the circuit board 100 that does not include the reinforcing member is less than 10 μm, the electrode layer 120 of the circuit board 100 is not stably protected, and thus the electrical reliability may be reduced. In addition, if the thickness of the layer of the first insulating layer 110 of the circuit board 100 that does not include the reinforcing member exceeds 40 μm, an overall thickness of the circuit board 100 increases, and accordingly, a thickness of the semiconductor package may increase. In addition, if the thickness of the layer of the first insulating layer 110 of the circuit board 100 that does not include the reinforcing member exceeds 40 μm, it may be difficult to miniaturize the electrode layer 120 of the circuit board 100.

The thickness may correspond to a vertical distance between electrode layers disposed on different layers. That is, the thickness may mean a length in a direction from the upper surface to the lower surface of the circuit board 100, or from the lower surface to the upper surface, and may mean a length in a vertical direction. Here, the upper surface may mean a highest position along the vertical direction in each component, and the lower surface may mean a lowest position along the vertical direction in each component. In addition, positions of the upper surface and the lower surface may be referred to as opposite to each other.

Meanwhile, the semiconductor package of the embodiment may include a second insulating layer 150 disposed on the upper surface of the circuit board 100. In addition, the semiconductor package may include a third insulating layer 160 disposed on the lower surface of the circuit board 100.

At this time, the upper surface of the circuit board 100 may mean an upper surface of the first insulating layer 110, and more specifically, the upper surface of the circuit board 100 may mean an upper surface of a first insulating layer disposed at an uppermost side among the plurality of first insulating layers. The lower surface of the circuit board 100 may refer to the lower surface of the first insulating layer 110, and more specifically, the lower surface of the circuit board 100 may refer to a lower surface of the first insulating layer disposed at a lowest side among the plurality of first insulating layers.

The second insulating layer 150 and the third insulating layer 160 may have a function of protecting the upper surface and the lower surface of the circuit board 100. Accordingly, the second insulating layer 150 and the third insulating layer 160 may be functionally referred to as a first protective layer and a second protective layer, respectively.

The second insulating layer 150 and the third insulating layer 160 may be resist layers. Preferably, the second insulating layer 150 and the third insulating layer 160 may be solder resist layers including an organic polymer material. For example, the second insulating layer 150 and the third insulating layer 160 may include an epoxy acrylate series resin. In detail, the second insulating layer 150 and the third insulating layer 160 may include a resin, a curing agent, a photoinitiator, a pigment, a solvent, a filler, an additive, an acrylic series monomer, etc. However, the embodiment is not limited thereto, and the second insulating layer 150 and the third insulating layer 160 may be any one of a photo solder resist layer, a cover-lay, and a polymer material.

For example, when a protruding portion 123 and the semiconductor device are bonded through solder, the solder and the solder resist layer do not have good wettability with each other, and thus, the solder can prevent a problem of electrical short-circuiting occurring between two adjacent protruding portions among the plurality of protruding portions 123.

A thickness of each of the second insulating layer 150 and the third insulating layer 160 may be 1 μm to 20 μm. The thickness of each of the second insulating layer 150 and the third insulating layer 160 may be 1 μm to 15 μm. For example, the thickness of each of the second insulating layer 150 and the third insulating layer 160 may be 5 μm to 20 μm. In this case, the thickness of the second insulating layer 150 may mean a vertical distance from an upper surface of an electrode layer disposed at an uppermost side to an upper surface of a second insulating layer 150. In addition, the thickness of the third insulating layer 160 may mean a vertical distance from a lower surface of an electrode layer disposed at a lowermost side to a lower surface of the third insulating layer 160.

If the thickness of each of the second insulating layer 150 and the third insulating layer 160 exceeds 20 μm, it may be difficult to thin the semiconductor package due to an increase in the thickness of the semiconductor package, or stress applied to the insulating layer 110 disposed between the second insulating layer 150 and the third insulating layer 160 may increase. That is, stress may be applied to the circuit board 100. If the thickness of each of the second insulating layer 150 and the third insulating layer 160 is less than 1 μm, it may be difficult to stably protect the electrode layer 120 included in the circuit board 100, and thus the electrical reliability or physical reliability may be deteriorated. The circuit board 100 may include an electrode layer 120. The electrode layer 120 may be disposed on a surface of the first insulating layer 110 of the circuit board 100. For example, when the first insulating layer 110 of the circuit board 100 has a five-layer structure, the electrode layers 120 may be disposed on surfaces of each of the five insulating layers.

At this time, one of the electrode layers 120 of the circuit board 100 may have an ETS (Embedded Trace Substrate) structure. For example, an electrode layer disposed on the upper surface of the circuit board 100 may have an ETS structure. For example, the electrode layer disposed on the upper surface of the circuit board 100 may be disposed in a recess provided on an upper surface of an uppermost first insulating layer 110. The ETS structure may also be referred to as an embedded structure. The ETS structure is advantageous for miniaturization compared to an electrode layer having a general protruding structure. Accordingly, the embodiment enables a formation of electrodes to correspond to a size and pitch of terminals provided in the semiconductor device. Through this, the embodiment can improve circuit integration. Furthermore, the embodiment can minimize a transmission distance of a signal transmitted through the semiconductor device, thereby minimizing signal transmission loss.

The electrode layer 120 can include a reinforcement electrode 122 electrically and/or physically separated from a signal electrode 121. The reinforcement electrode 122 can mean a dummy electrode physically and/or electrically separated from the signal electrode 121. However, the embodiment is not limited thereto. The reinforcement electrode 122 can be electrically connected to the signal electrode 121, and for example, can be connected to a ground electrode included in the signal electrode 121. Furthermore, the reinforcement electrode 122 can be used as a power electrode for supplying power to a connection member connected to a circuit board. Through this, the embodiment can stably supply power to the connection member, thereby allowing the connection member to operate stably. Specifically, the circuit board can supply sufficient power required for driving the connection member by providing a power signal to the connection member using the reinforcement electrode 122. Accordingly, the embodiment can improve the driving characteristics of the connection member. That is, the embodiment can solve the problem of insufficient power provided to the connection member. That is, recently, the function provided by the connection member has increased or the performance has been improved, so a driving power required by the connection member can increase. Accordingly, the embodiment can supply a power signal to the connection member through the reinforcement pattern, and through this, the embodiment can further improve the electrical reliability of the semiconductor package.

In addition, the reinforcement electrode 122 can transfer heat generated from the circuit board 100 to an outside. Through this, the embodiment can improve heat dissipation characteristics of the circuit board 100. When the reinforcement electrode 122 is connected to the signal electrode 121, heat can be transferred to the outside through the ground electrode, for example. However, even if the reinforcement electrode 122 is physically and/or electrically separated from the signal electrode 121, heat generated from the circuit board 100 can be transferred to the outside through the reinforcement electrode.

The reinforcement electrode 122 of the embodiment can be disposed on the circuit board 100 to prevent physical deformation such as bending of the circuit board 100. The reinforcement electrode 122 can have a function of preventing the circuit board 100 from being bent in a specific direction. In addition, the reinforcement electrode 122 can function as a power line that enables stable power supply to the connection member disposed on the circuit board 100.

A specific structure of the reinforcement electrode 122 will be described in more detail below.

The circuit board of the embodiment includes the reinforcement electrode 122. This can also be called a reinforcement member that functions to prevent physical deformation of the circuit board. A reason the reinforcement member is called the reinforcement electrode 122 is because the reinforcement member is a part of the electrode layer 120. However, the embodiment is not limited thereto. For example, a reinforcement member may include a different material from the electrode layer. For example, the reinforcement member may include an insulating material such as silicon or ceramic.

Meanwhile, the electrode layer 120 may include a protruding portion 123. The protruding portion 123 may protrude on the circuit board 100 in a direction away from the circuit board 100. The protruding portion 123 may be disposed on the signal electrode 121 of the electrode layer 120. The protruding portion 123 may be disposed to protrude upward on the signal electrode disposed at an uppermost side among the electrode layers 120. However, the embodiment is not limited thereto. For example, the protruding portion 123 may be disposed to protrude downward on a lower surface of the signal electrode disposed at a lowermost side among the electrode layers 120.

The protruding portion 123 may be referred to as a bump. The protruding portion 123 may also be referred to as a post. The protruding portion 123 may be referred to as a pillar. A semiconductor device may be disposed on the signal electrode 121 of the circuit board 100. In contrast, an interposer coupled with the semiconductor device may be bonded to the signal electrode 121 of the circuit board 100. At this time, as a pitch of the terminal of the semiconductor device or the electrode of the interposer becomes finer, a problem of short-circuiting of the conductive connecting parts disposed on the plurality of terminals or electrodes may occur. Therefore, in order to reduce a volume of the conductive connecting parts disposed on each of the plurality of terminals or electrodes, the signal electrode 121 may include a protruding portion 123. In addition, when using TC (Thermal Compression) bonding that applies heat and pressure to the conductive connecting parts disposed between the circuit board 100 and the semiconductor device or the interposer to bond them, the protruding portion 123 may have a function of improving an alignment between the signal electrode 121 and a terminal of the semiconductor device or an electrode of the interposer. Furthermore, the protruding portion 123 may have a function of preventing diffusion of the conductive connecting parts.

The electrode layer 120 of the circuit board 100 may be formed of at least one metal material selected from gold (Au), silver (Ag), platinum (Pt), titanium (Ti), tin (Sn), copper (Cu), and zinc (Zn). In addition, the electrode layer 120 of the circuit board 100 may be formed of a paste or solder paste including at least one metal material selected from gold (Au), silver (Ag), platinum (Pt), titanium (Ti), tin (Sn), copper (Cu), and zinc (Zn) having excellent bonding strength. Preferably, the electrode layer 120 of the circuit board 100 may be formed of copper (Cu) which has high electrical conductivity and is relatively inexpensive.

The signal electrode 121 and the reinforcement electrode 122 of the electrode layer 120 may include a same metal material, but are not limited thereto. However, in order to simplify a manufacturing process of the circuit board 100, the signal electrode 121 and the reinforcement electrode 122 may include a same metal material.

The electrode layer 120 of the circuit board 100 may have a thickness in a range of 7 μm to 20 μm. For example, the electrode layer 120 of the circuit board 100 may have a thickness in a range of 9 μm to 17 μm. The electrode layer 120 of the circuit board 100 may have a thickness in a range of 10 μm to 13 μm. If the thickness of the electrode layer 120 of the circuit board 100 is less than 7 μm, a resistance of the electrode layer 120 may increase, and an allowable current of a transmittable signal may decrease. In addition, if the thickness of the electrode layer 120 of the circuit board 100 exceeds 20 μm, it may be difficult to miniaturize the electrode layer 120 and to thin the circuit board 100.

The electrode layer 120 of the circuit board 100 may include a through pad connected to the through part 130 of the circuit board 100 and at least one electrode pattern connected to an external circuit board or semiconductor device. In addition, the electrode layer 120 of the circuit board 100 may include a trace of a signal transmission line connected to the through pad or the electrode pattern. The through pad or electrode pattern of the electrode layer 120 of the circuit board 100 may have a width in a range of 15 μm to 90 μm. The through pad or electrode pattern of the electrode layer 120 of the circuit board 100 may have a width in a range of 20 μm to 85 μm. The through pad or electrode pattern of the electrode layer 120 of the circuit board 100 may have a width in a range of 25 μm to 80 μm.

At this time, the through pad or electrode pattern of the electrode layer 120 of the circuit board 100 may have different widths within the range described above depending on functions. In addition, the electrodes of the electrode layer 120 of the circuit board 100 may have different widths corresponding to a size of the terminal of the connected semiconductor device or a size of the pad of the external circuit board.

Meanwhile, when the signal electrode 121 includes a protruding portion 123, a width of the protruding portion 123 may have a range of 40 μm to 70 μm. If the width of the protruding portion 123 is smaller than 40 μm, the width of protruding portion 123 is too small and may cause collapse problems during TC bonding. In addition, if the width of the protruding portion 123 is greater than 70 μm, it may have a problem of difficulty in corresponding to the fine pitch of the terminal of the semiconductor device or the electrode of the interposer.

The electrode layer 120 may include a through part 130. That is, the electrode layer includes the electrode layer 120 and the through part 130, and the electrode layer 120 may have an electrode pattern. The width of the through part 130 may be narrower than the width of the through pad that is the same width as the through part, and the lower surface of the through pad may be on the same plane as the lower surface of the electrode pattern.

The through part 130 may pass through the first insulating layer 110 of the circuit board 100. The through part 130 of the circuit board 100 may connect between electrode layers disposed on different insulating layers of the circuit board 100. The through part 130 may have a function of vertically connecting between electrode layers disposed on different layers.

A thickness of the through part 130 in a vertical direction may be greater than a thickness of the electrode layer 120 in the vertical direction. When the electrode layer 120 is embedded in the first insulating layer 110, the through part 130 may penetrate between electrode layers disposed in the first insulating layer. In addition, when the electrode layer protrudes from the upper and lower surfaces of the first insulating layer, the through part 130 can pass through the insulating layer as a whole.

The through part 130 of the circuit board 100 can be formed by filling an inside of a through hole passing through the first insulating layer 110 of the circuit board 100 with a conductive material.

The through hole can be formed by any one of mechanical, laser, and chemical processing methods. When the through hole is formed by mechanical processing, methods such as milling, drilling, and routing can be used. In addition, when the through hole is formed by laser processing, a UV or CO2 laser method can be used. In addition, when the through hole is formed by chemical processing, a chemical containing amino silane, ketones, etc. can be used.

When the through hole is formed, the inside of the through hole can be filled with a conductive material to form the through part 130 of the circuit board 100. A metal material forming the through parts may be any one material selected from copper (Cu), silver (Ag), tin (Sn), gold (Au), nickel (Ni), and palladium (Pd). In addition, the conductive material filling may utilize any one of electroless plating, electrolytic plating, screen printing, sputtering, evaporation, ink-jetting, and dispensing, or a combination thereof.

Meanwhile, when the first insulating layer 110 includes a core layer, the through part 130 passing through the core layer may include an insulating member 140. The insulating member 140 may be provided to fill a portion of a through hole passing through the core layer. The insulating member 140 may also be referred to as a hole plugging member. The insulating member 140 may include an insulating material provided in a through hole of the core layer. For example, the insulating member 140 may include a paste of an insulating ink material. For example, the insulating member 140 may include a plugging ink. However, the embodiment is not limited thereto. For example, the insulating member 140 may include a conductive material. Specifically, the insulating member 140 may include a conductive paste containing a conductive metal powder.

Hereinafter, the reinforcement electrode 122 of the electrode layer 120 according to the first embodiment will be specifically described.

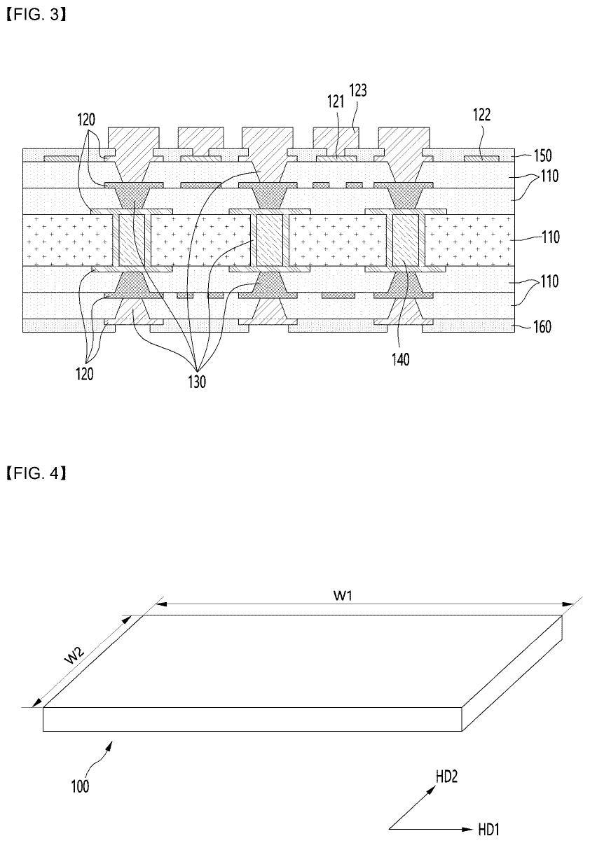

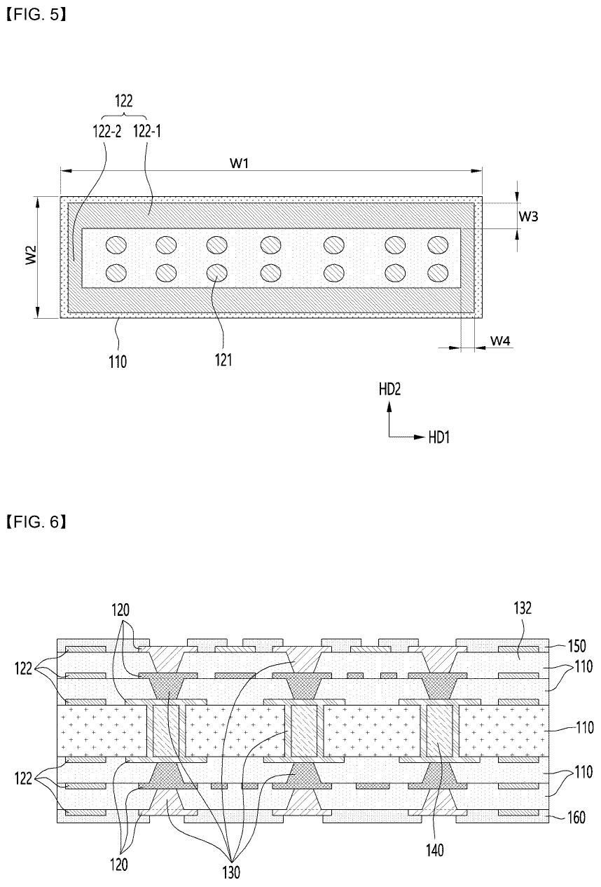

FIG. 4 is a perspective view schematically showing a circuit board according to an embodiment, and FIG. 5 is a plan view showing a reinforcement pattern according to an embodiment.

Referring to FIG. 4, the circuit board 100 may have a hexahedral shape. Accordingly, the planar shape of the circuit board 100 may have a square shape. However, the embodiment is not limited thereto. For example, a planar shape of the circuit board 100 may have one of a circular shape, an elliptical shape, a triangular shape, and a polygonal shape. However, for convenience of explanation, a planar shape of the circuit board 100 is described as having a square shape.

The planar shape of the circuit board 100 may be a rectangle. For example, a width W1 of the circuit board 100 in a first horizontal direction HD1 may be different from a width W2 of the circuit board 100 in a second horizontal direction HD2.

The first horizontal direction HD1 may mean a width direction or an x-axis direction. Preferably, the first horizontal direction HD1 may mean a long-axis direction having a relatively great width compared to the second horizontal direction HD2 in a plane of the circuit board 100.

The second horizontal direction HD2 may mean a length direction or a y-axis direction. Preferably, the second horizontal direction HD2 may mean a short-axis direction having a relatively smaller width than the first horizontal direction HD1 in the plane of the circuit board 100. The second horizontal direction HD2 may mean a direction perpendicular to the first horizontal direction HD1.

The width W1 of the circuit board 100 in the first horizontal direction HD1 may be greater than the width W2 of the second horizontal direction HD2. The width W1 of the circuit board 100 in the first horizontal direction HD1 may be 1.3 times or more the width W2 of the second horizontal direction HD2. Preferably, the width W1 of the circuit board 100 in the first horizontal direction HD1 may be 1.5 times or more the width W2 of the second horizontal direction HD2. More preferably, the width W1 of the circuit board 100 in the first horizontal direction HD1 may be 1.8 times or more the width W2 of the second horizontal direction HD2. For example, a plurality of semiconductor devices may be disposed on the circuit board 100. For example, the semiconductor package may include two semiconductor devices arranged on the circuit board 100. At this time, the first horizontal direction HD1 may mean a direction in which the two semiconductor devices are spaced apart. In addition, if the width W1 of the circuit board 100 in the first horizontal direction HD1 is less than 1.3 times the width W2 in the second horizontal direction HD2, a space that is meaninglessly wasted in a structure in which the plurality of semiconductor devices are disposed may increase, and thus an overall area of the circuit board 100 may increase. In addition, if the width W1 of the circuit board 100 in the first horizontal direction HD1 exceeds 5 times the width W2 of the second horizontal direction HD2, a separation distance between terminals of a plurality of semiconductor devices disposed on the circuit board 100 or between electrodes of the interposer may increase. In addition, if the separation distance increases, a signal transmission distance may increase and thus signal transmission loss may increase. Accordingly, the width W1 of the circuit board 100 in the first horizontal direction HD1 is set to have a range of 1.3 to 5 times the width W2 of the second horizontal direction HD2.

Meanwhile, referring to FIG. 5, an electrode layer 120 may be disposed on the circuit board 100. Preferably, a signal electrode 121 and a reinforcement electrode 122 may be disposed on the first insulating layer 110 of the circuit board 100.

At this time, the reinforcement electrode 122 may be disposed in a circumferential region on a plane of the circuit board 100 adjacent to a side surface of the circuit board 100. For example, the reinforcement electrode 122 may be disposed along an outer region or an edge region of an upper surface of the circuit board 100 adjacent to the side surface of the circuit board 100.

For example, the reinforcement electrode 122 may be disposed on the circuit board 100 in a closed loop shape along the circumferential direction of the circuit board 100. Through this, the embodiment can more efficiently prevent the circuit board 100 from bending. Accordingly, the embodiment can improve electrical reliability and/or physical reliability of the circuit board 100.

However, the embodiment is not limited thereto. The reinforcement electrode 122 may have an open loop shape along the circumferential direction on the circuit board 100. In one embodiment, when the reinforcement electrode 122 has an open loop shape, the reinforcement electrode 122 may have one electrode pattern in which an open region is formed between one end and another end. In another embodiment, when the reinforcement electrode 122 has an open loop shape, the reinforcement electrode 122 may include a plurality of electrode patterns that are spaced apart from each other.

The reinforcement electrode 122 may include a first electrode part 122-1 disposed on the circuit board 100 in the first horizontal direction HD1. The first electrode part 122-1 may be disposed on the circuit board 100 to extend long in the first horizontal direction HD1. For example, the first electrode part 122-1 of the reinforcement electrode 122 may be disposed on the circuit board 100 along a longitudinal axis direction of the circuit board 100.

The reinforcement electrode 122 may include a second electrode part 122-2 disposed on the circuit board 100 in a second horizontal direction HD2 different from the first horizontal direction HD1. The second horizontal direction HD2 may be a direction perpendicular to the first horizontal direction HD1 as described above, but is not limited thereto. The second electrode part 122-2 may be disposed on the circuit board 100 to extend long in the second horizontal direction HD2. For example, the second electrode part 122-2 of the reinforcement electrode 122 may be disposed on the circuit board 100 along a short axis direction of the circuit board 100.

The first electrode part 122-1 and the second electrode part 122-2 of the reinforcement electrode 122 may have an integral structure that is connected to each other, but is not limited thereto. For example, at least one open region may be provided between the first electrode part 122-1 and the second electrode part 122-2. Accordingly, a separation portion may be provided between the first electrode part 122-1 and the second electrode part 122-2.

A width W3 of the first electrode part 122-1 of the reinforcement electrode 122 may be different from a width W4 of the second electrode part 122-2 of the reinforcement electrode 122.

When the width W1 of the first horizontal direction HD1 of the circuit board 100 and the width W2 of the second horizontal direction HD2 are different from each other, the stresses applied in the first horizontal direction HD1 and the second horizontal direction HD2 may be different from each other. Accordingly, based on a magnitude of the applied stress, the width W3 of the first electrode part 122-1 may be disposed differently from the width W4 of the second electrode part 122-2 of the reinforcement electrode 122. In the above-described embodiment, the width W1 of the first horizontal direction HD1 is greater than the width W2 of the second horizontal direction HD2, and accordingly, a magnitude of the stress applied along the first horizontal direction HD1 is greater than a magnitude of the stress applied along the second horizontal direction HD2, and thus, the width W3 of the first electrode part 122-1 is described as being greater than the width W4 of the second electrode part 122-2 of the reinforcement electrode 122. However, if the stress applied in the second horizontal direction is greater than the stress applied in the first horizontal direction, the width W3 of the first electrode part 122-1 may be disposed to be smaller than the width W4 of the second electrode part 122-2 of the reinforcement electrode 122 depending on the magnitude of the stress.

In this embodiment, preferably, the width W3 of the first electrode part 122-1 may be greater than the width W4 of the second electrode part 122-2.

At this time, the width W3 of the first electrode part 122-1 may mean a width of the second horizontal direction HD2 of the first electrode part 122-1. In addition, the width W4 of the second electrode part 122-2 may mean a width of the first horizontal direction HD1 of the second electrode part 122-2.

At this time, a difference between the width W3 of the first electrode part 122-1 in the second horizontal direction HD2 and the width W4 of the second electrode part 122-2 in the first horizontal direction HD1 can be determined based on the difference between the width W1 of the first horizontal direction HD1 and the width W2 of the second horizontal direction HD2 of the circuit board 100. For example, the difference between the width W3 of the first electrode part 122-1 in the second horizontal direction HD2 and the width W4 of the second electrode part 122-2 in the first horizontal direction HD1 can be determined based on a difference in stress applied in the first horizontal direction HD1 and the second horizontal direction HD2 that changes due to the difference between the width W1 of the first horizontal direction HD1 and the width W2 of the second horizontal direction HD2.

At this time, the width W3 of the first electrode part 122-1 in the second horizontal direction HD2 may have a range of 1.3 to 5 times the width W4 of the second electrode part 122-2 in the first horizontal direction HD1. Preferably, the width W3 of the first electrode part 122-1 in the second horizontal direction HD2 may have a range of 1.5 to 4 times the width W4 of the second electrode part 122-2 in the first horizontal direction HD1. More preferably, the width W3 of the first electrode part 122-1 in the second horizontal direction HD2 may have a range of 1.8 to 4 times the width W4 of the second electrode part 122-2 in the first horizontal direction HD1.

If the width W3 of the first electrode part 122-1 in the second horizontal direction HD2 is less than 1.3 times the width W2 of the second electrode part 122-2 in the first horizontal direction HD1, an effect of improving warpage characteristics of the circuit board 100 caused by the reinforcement electrode 122 may be insignificant. Specifically, the circuit board 100 may experience bending concentrated in a portion having a relatively large width among the first horizontal direction HD1 and the second horizontal direction HD2. Accordingly, the embodiment allows the width W3 of the first electrode part 122-1 of the reinforcement electrode 122 disposed in the first horizontal direction HD1 of the circuit board 100 to be greater than the width W4 of the second electrode part 122-2. Accordingly, the embodiment can further improve warpage characteristics of the circuit board 100 while minimizing an area occupied by the reinforcement electrode 122 on the circuit board 100. In addition, if the width W3 of the first electrode part 122-1 in the second horizontal direction HD2 exceeds five times the width W2 of the second electrode part 122-2 in the first horizontal direction HD1, a problem may occur in which an area of the circuit board 100 becomes greater due to the arrangement of the reinforcement electrode 122.

Specifically, the width W3 of the first electrode part 122-1 can satisfy a range of 50 μm to 90 μm. Preferably, the width W3 of the first electrode part 122-1 can satisfy a range of 55 μm to 85 μm. More preferably, the width W3 of the first electrode part 122-1 can satisfy a range of 60 μm to 80 μm. If the width W3 of the first electrode part 122-1 is less than 50 μm, an effect of improving warpage characteristics of the circuit board 100 by the first electrode part 122-1 may be insignificant. If the width W3 of the first electrode part 122-1 exceeds 90 μm, an area occupied by the reinforcement electrode 122 on the circuit board increases, which may increase the stress, and an unnecessary area where the semiconductor device is not mounted may increase, which may waste cost and materials.

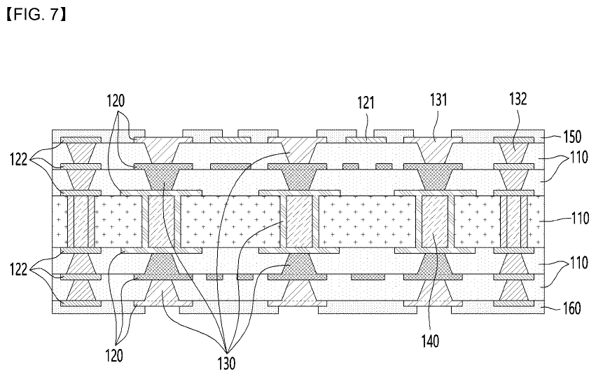

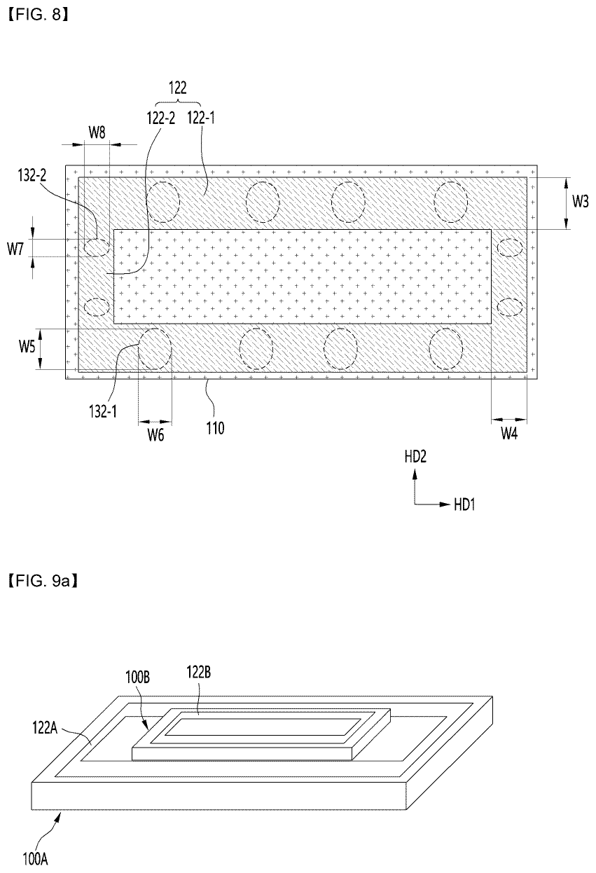

FIG. 6 is a drawing showing a circuit board according to a second embodiment, FIG. 7 is a drawing showing a circuit board according to a third embodiment, and FIG. 8 is a plan view showing reinforcement electrodes and reinforcement through parts of a circuit board of FIG. 7.

Referring to FIG. 6, a circuit board according to the second embodiment may include a first insulating layer 110, an electrode layer 120, a through part 130, an insulating member 140, a second insulating layer 150, and a third insulating layer 160. At this time, the electrode layer 120 may include a signal electrode 121 and a reinforcement electrode 122. In addition, the reinforcement electrode 122 may be provided on at least two layers among the plurality of layers constituting the first insulating layer 110. Through this, the embodiment may further prevent the circuit board 100 from being bent in a specific direction.

Although not illustrated, reinforcement electrodes 122 disposed on the plurality of layers may overlap each other vertically and may include non-overlapping portions. The reinforcement electrode 122 disposed in each of the plurality of layers according to a magnitude of the stress and an applied direction of the stress may have a structure overlapping in a vertical direction, thereby having an effect of having an overall thicker structure. In addition, in a case of having a non-overlapping portion, the reinforcement electrode 122 may be disposed to have an opening with a wider width toward the circuit board 100. By arranging the reinforcement electrode 122 that is wider toward the circuit board 100, it is possible to provide an effect that gradually reduces the magnitude of stress applied in a direction toward the semiconductor device, so that the stress applied to the semiconductor package gradually reduces toward the semiconductor device. Accordingly, a difference in the stress applied to each of the plurality of layers constituting the first insulating layer 110 may be controlled so as not to become too large, thereby improving electrical and physical reliability of the semiconductor device package.

The reinforcement electrode 122 may have a same thickness as the signal electrode 121, and when the stress is large, a thickness of the reinforcement electrode 122 may be thicker than a thickness of the signal electrode 121. That is, it can be freely disposed according to a size of the circuit board and a magnitude of the stress.

Referring to FIGS. 7 and 8, the circuit board according to the third embodiment is different from the circuit board of the second embodiment in that it further includes a reinforcing through part.

For example, the circuit boards according to the first and second embodiments include a through part 130. At this time, the through part 130 includes only a signal through part connected to the signal electrode 121 of the electrode layer 120 in the circuit board.

Unlike this, the circuit board of the third embodiment includes a through electrode 130. The through electrode 130 includes a first through part 131 connected to the signal electrode 121. Furthermore, the through electrode 130 of the circuit board of the third embodiment may include a second through part 132.

The first through part 131 may be connected to the signal electrode 121 of the electrode layer 120.

In addition, the second through part 132 may be connected to the reinforcement electrode 122. For example, the second through part 132 may connect between a plurality of reinforcement electrodes 122 disposed in different layers of the circuit board 100.

The second through part 132 may more effectively prevent the circuit board 100 from being bent by passing through the first insulating layer 110. Furthermore, the second through part 132 may transfer heat between the reinforcement electrodes 122 by connecting between the plurality of reinforcement electrodes 122. Through this, the embodiment may dissipate heat generated in the circuit board 100 by using the second through part 132, thereby improving the heat dissipation characteristics of the circuit board 100. Furthermore, the reinforcement electrode 122 may be used as a power electrode for supplying power to a connection member connected to the circuit board. Through this, the embodiment can supply stable power to the connection member, thereby enabling the connection member to operate stably. Specifically, the circuit board can supply sufficient power required for driving the connection member by providing a power signal to the connection member using the reinforcement electrode 122. Accordingly, the embodiment can improve the driving characteristics of the connection member. That is, the embodiment can solve a problem of insufficient power provided to the connection member. That is, recently, the function provided by the connection member has increased or the performance of by the connection member has been improved, so that the driving power required by the connection member can increase. Accordingly, the embodiment can supply a power signal to the connection member through the reinforcement pattern, thereby further improving the electrical reliability of the semiconductor package.

Meanwhile, the second through part 132 can be divided into a plurality of parts.

For example, the second through part 132 can include a first through part 132-1.

The first through part 132-1 may be vertically overlapped with a part of the reinforcement electrode 122. Preferably, the first through part 132-1 may be vertically overlapped with the first electrode part 122-1 of the reinforcement electrode 122. More preferably, the first through part 132-1 may be connected with the first electrode part 122-1 of the reinforcement electrode 122.

A width W5 of the second horizontal direction HD2 of the first through part 132-1 may be different from a width W6 of the first horizontal direction HD1 of the first through part 132-1. For example, a planar shape of the first through part 132-1 may have an elliptical shape or a rectangular shape in which the width W5 of the second horizontal direction HD2 is greater than the width W6 of the first horizontal direction HD1. Therefore, the embodiment can prevent bending of the first circuit board 100 having a relatively large width in the first horizontal direction HD1 through the first through part 132-1.

The second through part 132-2 may vertically overlap a portion of the reinforcement electrode 122. Preferably, the second through part 132-2 may be vertically overlapped with the second electrode part 122-2 of the reinforcement electrode 122. More preferably, the second through part 132-2 may be connected to the second electrode part 122-2 of the reinforcement electrode 122.

A width W7 of the second horizontal direction HD2 of the second through part 132-2 may be different from a width W8 of the first horizontal direction HD1 of the second through part 132-2. For example, a planar shape of the second through part 132-2 may have an oval shape or a rectangular shape in which the width W7 of the second horizontal direction HD2 is smaller than the width W8 of the first horizontal direction HD1.

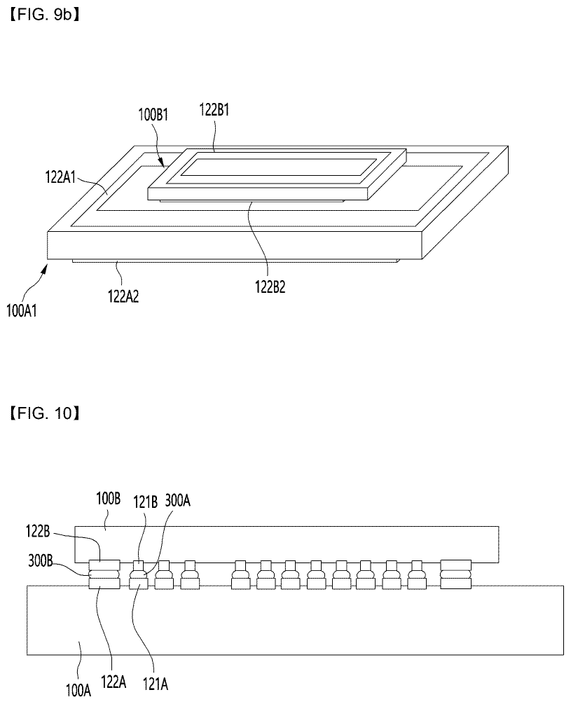

FIG. 9a is a drawing showing a semiconductor package including a plurality of circuit boards according to one embodiment, FIG. 9b is a drawing showing a semiconductor package including a plurality of circuit boards according to another embodiment, and FIG. 10 is a cross-sectional view showing a semiconductor package according to one embodiment.

Referring to FIG. 9a, a semiconductor package according to one embodiment may include a first circuit board 100A and a second circuit board 100B. The first circuit board 100A and the second circuit board 100B may represent the first circuit board 1100 and the second circuit board 1200 illustrated in FIG. 2a, but are not limited thereto.

At this time, the first circuit board 100A and the second circuit board 100B may each have a structure corresponding to the circuit board 100 described in the previous drawing.

However, the first circuit board 100A may mean a package substrate. In addition, the second circuit board 100B may mean an interposer disposed on the package substrate. Therefore, a total planar area of the first circuit board 100A may be greater than a total planar area of the second circuit board 100B. At this time, the first circuit board 100A may be referred to as a main circuit board of the semiconductor package, and for the convenience of explanation of the second circuit board 100B, it may be referred to as a connection member connected to the first circuit board.

The first circuit board 100A includes a first reinforcement electrode 122A. In addition, the second circuit board 100B includes a second reinforcement electrode 122B.

In one embodiment, the first reinforcement electrode 122A of the first circuit board 100A and the second reinforcement electrode 122B of the second circuit board 100B may not overlap each other in a vertical direction. Accordingly, in the above-described exemplary embodiment, the first reinforcement electrode 122A of the first circuit board 100A and the second reinforcement electrode 122B of the second circuit board 100B are prevented from vertically overlapping each other, thereby minimizing the area occupied by the first reinforcement electrode 122A and the second reinforcement electrode 122B, and improving warpage characteristics of the semiconductor package including the first circuit board 100A and the second circuit board 100B as a whole. Furthermore, the reinforcement electrodes 122A and 122B can be used as power electrodes for supplying power to a connection member connected to the circuit board. Through this, the embodiment can stably supply power to the connection member, thereby allowing the connection member to operate stably. Specifically, the circuit board can supply sufficient power necessary for driving the connection member by providing a power signal to the connection member using the reinforcement electrode 122. Accordingly, the embodiment can improve driving characteristics of the connection member. That is, the embodiment can solve a problem of insufficient power provided to the connection member. That is, recently, the function provided by the connection member has increased or the performance of the connection member has improved, so the driving power required by the connection member can increase. Accordingly, the embodiment can supply a power signal to the connection member through the reinforcement pattern, and through this, the embodiment can further improve the electrical reliability of the semiconductor package.

Referring to FIG. 9b, in another embodiment, the first circuit board 100A1 can include a plurality of reinforcement electrodes. For example, the first circuit board 100A1 can include a first reinforcement electrode 122A1 disposed on the first circuit board 100A1 and a second reinforcement electrode 122A2 disposed under the first circuit board 100A1.

The second circuit board 100B1 can include a plurality of reinforcement electrodes. For example, the second circuit board 100B1 may include a first reinforcement electrode 122B1 disposed on the second circuit board 100B1 and a second reinforcement electrode 122B2 disposed under the first circuit board 100B1. Through this, the embodiment may minimize physical deformation of the circuit board and further minimize physical deformation of the semiconductor package.

Meanwhile, referring to FIG. 10, the first reinforcement electrode 122A of the first circuit board 100A and the second reinforcement electrode 122B of the second circuit board 100B may overlap each other in the vertical direction. In this case, the first reinforcement electrode 122A of the first circuit board 100A may be connected to the second reinforcement electrode 122B of the second circuit board 100B. The connection between the first reinforcement electrode 122A and the second reinforcement electrode 122B may include either an electrical connection or a physical connection between the first reinforcement electrode 122A and the second reinforcement electrode 122B.

The first reinforcement electrode 122A may be disposed on the upper surface of the first circuit board 100A. At this time, the first reinforcement electrode 122A may include a portion embedded in the first circuit board 100A and a portion protruding from the embedded portion toward the second circuit board 100B.

In addition, the first circuit board 100A may include a first signal electrode 121A spaced apart from the first reinforcement electrode 122A. The first signal electrode 121A may also include an embedded portion and a protruded portion corresponding to the first reinforcement electrode 122A.

In addition, the second reinforcement electrode 122B may be disposed on the lower surface of the second circuit board 100B. At this time, the second reinforcement electrode 122B may include a portion embedded in the lower surface of the second circuit board 100B and a portion protruding from the embedded portion toward the first circuit board 100A. In addition, the second circuit board 100B may include a second signal electrode 121B spaced apart from the second reinforcement electrode 122B. The second signal electrode 121B may also include an embedded portion and a protruded portion corresponding to the second reinforcement electrode 122B.

At this time, a connecting part may be disposed between the first circuit board 100A and the second circuit board 100B.

The connecting part may include a first connecting part 300A disposed between the first signal electrode 121A of the first circuit board 100A and the second signal electrode 121B of the second circuit board 100B. The first connecting part 300A may electrically connect the first signal electrode 121A of the first circuit board 100A and the second signal electrode 121B of the second circuit board 100B.

In addition, the connecting part may include a second connecting part 300B disposed between the first reinforcement electrode 122A of the first circuit board 100A and the second reinforcement electrode 122B of the second circuit board 100B. The second connecting part 300B above can mutually couple the first reinforcement electrode 122A of the first circuit board 100A and the second reinforcement electrode 122B of the second circuit board 100B. Through this, the embodiment can further enhance a bonding force between the first circuit board 100A and the second circuit board 100B through the arrangement of the second connecting part 300B that couples the first reinforcement electrode 122A and the second reinforcement electrode 122B. Through this, the embodiment can further enhance the physical reliability and/or electrical reliability of the semiconductor package.

In addition, the embodiment can enable heat generated in the first circuit board 100A to be dissipated through the second circuit board 100B via the second connecting part 300B, or can enable heat generated in the second circuit board 100B to be dissipated through the first circuit board 100A. Through this, the embodiment can further improve the heat dissipation characteristics of the semiconductor package.

On the other hand, when the semiconductor package having the above-described characteristics of the invention is used in an IT device or home appliance such as a smart phone, a server computer, a TV, and the like, functions such as signal transmission or power supply can be stably performed. For example, the semiconductor package having the features of the present invention can function to safely protect the semiconductor device from external moisture or contaminants, or alternatively, it is possible to solve problems of leakage current, electrical short circuit between terminals, and electrical opening of terminals supplied to the semiconductor device. In addition, when the function of signal transmission is in charge, it is possible to solve the noise problem. Through this, the semiconductor package having the above-described characteristics of the invention can maintain the stable function of the IT device or home appliance, so that the entire product and the semiconductor package to which the present invention is applied can achieve functional unity or technical interlocking with each other.

When the semiconductor package having the characteristics of the invention described above is used in a transport device such as a vehicle, it is possible to solve the problem of distortion of a signal transmitted to the transport device, or alternatively, the safety of the transport device can be further improved by safely protecting the semiconductor device that controls the transport device from the outside and solving the problem of leakage current or electrical short between terminals or the electrical opening of the terminal supplied to the semiconductor device. Accordingly, the transportation device and the semiconductor package to which the present invention is applied can achieve functional integrity or technical interlocking with each other.

The characteristics, structures and effects described in the embodiments above are included in at least one embodiment but are not limited to one embodiment. Furthermore, the characteristics, structures, and effects and the like illustrated in each of the embodiments may be combined or modified even with respect to other embodiments by those of ordinary skill in the art to which the embodiments pertain. Thus, it should be construed that contents related to such a combination and such a modification are included in the scope of the embodiment.

The above description has been focused on the embodiment, but it is merely illustrative and does not limit the embodiment. A person skilled in the art to which the embodiment pertains may appreciate that various modifications and applications not illustrated above are possible without departing from the essential features of the embodiment. For example, each component particularly represented in the embodiment may be modified and implemented. In addition, it should be construed that differences related to such changes and applications are included in the scope of the embodiment defined in the appended claims.

1. A circuit board comprising:
an insulating structure; and
a reinforcement pattern disposed on the insulating structure,
wherein the reinforcement pattern includes:
a first reinforcement part extending on the insulating structure in a first horizontal direction, and
a second reinforcement part extending on the insulating structure in a second horizontal direction perpendicular to the first horizontal direction, and
wherein a width of the insulating structure in the first horizontal direction is greater than a width of the insulating structure in the second horizontal direction, and
wherein a width of the first reinforcement part in the second horizontal direction is greater than a width of the second reinforcement part in the first horizontal direction.

2. The circuit board of claim 1, wherein the reinforcement pattern is disposed at a position spaced apart from an edge of an upper surface of the insulating structure along the first horizontal direction and the second horizontal direction.

3. The circuit board of claim 1, further comprising:
an embedded reinforcement pattern embedded within the insulating structure.

4. The circuit board of claim 3, wherein the reinforcement pattern overlaps the embedded reinforcement pattern along a vertical direction.

5. The circuit board of claim 1, wherein the width of the first reinforcement part in the second horizontal direction satisfies a range of 1.3 to 5 times the width of the second reinforcement part in the first horizontal direction.

6. The circuit board of claim 5, wherein the width of the first reinforcement part in the second horizontal direction satisfies a range of 50 μm to 90 μm.

7. The circuit board of claim 1, wherein the reinforcement pattern is disposed on the insulating structure in a closed loop shape, and wherein the first reinforcement part is connected to the second reinforcement part.

8. The circuit board of claim 4, further comprising:
a reinforcement through electrode passing through at least a part of the insulating structure along a vertical direction and connecting the reinforcement pattern and the embedded reinforcement pattern.

9. The circuit board of claim 8, further comprising:
a signal electrode disposed on the insulating structure, and
wherein the signal electrode is disposed further away from an outer surface of the insulating structure than the reinforcement pattern.

10. The circuit board of claim 9, wherein the reinforcement pattern, the embedded reinforcement pattern, and the reinforcement through electrode are a power line for supplying power to the connection member.

11. The circuit board of claim 9, wherein the signal electrode includes a plurality of electrode patterns spaced apart from each other along the first horizontal direction and the second horizontal direction, and
wherein the reinforcement pattern is disposed to surround the plurality of electrode patterns at a position spaced apart from the plurality of electrode patterns.

12. The circuit board of claim 9, further comprising:
a connection member disposed on the signal electrode.

13. The circuit board of claim 12, wherein the connection member is electrically connected to the reinforcement pattern, the embedded reinforcement pattern, and the reinforcement through electrode.

14. The circuit board of claim 8, wherein the reinforcement through electrode includes:
a first through part vertically overlapping the first reinforcement part; and
a second through part vertically overlapping the second reinforcement part.

15. The circuit board of claim 14, wherein a width of the first through part in the first horizontal direction is greater than a width of the first through part in the second horizontal direction.

16. The circuit board of claim 15, wherein a width of the second through part in the first horizontal direction is smaller than a width of the second through part in the second horizontal direction.

17. The circuit board of claim 16, wherein a planar area of the first through part is greater than a planar area of the second through part.

18. A circuit board comprising:
a first build-up structure including a plurality of insulating layers laminated along a vertical direction;
a connecting part disposed on the first build-up structure;
a first reinforcement member disposed on the first build-up structure and spaced apart from the connecting part;
a second build-up structure disposed on the connecting part and including a plurality of insulating layers laminated along the vertical direction; and
a second reinforcement member disposed on the second build-up structure,
wherein each of the first reinforcement member and the second reinforcement member includes:
a first reinforcement part extending in a first horizontal direction and having a first width along a second horizontal direction perpendicular to the first horizontal direction, and
a second reinforcement part extending in the second horizontal direction and having a second width different from the first width along the first horizontal direction.

19. The circuit board of claim 18, wherein the first reinforcement member and the second reinforcement member do not overlap each other along the vertical direction.

20. The circuit board of claim 19, wherein the first reinforcement member and the second reinforcement member overlap each other along the vertical direction, and
wherein the connecting part is further disposed between the first reinforcement member and the second reinforcement member.
